(19) United States
(12) Patent Application Publication
(10) Pub. No.: US 2026/0090071 A1
(43) Pub. Date: Mar. 26, 2026

(54) SEMICONDUCTOR DEVICE WITH STRESS LINER AND BACKSIDE CONTACT

(71) Applicant: INTERNATIONAL BUSINESS MACHINES CORPORATION, ARMONK, NY (US)

(72) Inventors: Ruilong Xie, Niskayuna, NY (US); Kisik Choi, Watervliet, NY (US); Chen Zhang, Santa Clara, CA (US); Jingyun Zhang, Albany, NY (US)

(21) Appl. No.: 18/892,286

(22) Filed: Sep. 20, 2024

(51) Int. Cl. H01L 21/8234; H01L 27/088; H01L 29/06; H01L 29/08; H01L 29/417; H01L 29/423; H01L 29/66; H01L 29/775; H01L 29/78; H01L 29/786

(52) U.S. Cl. CPC H10D 84/038; H10D 30/014; H10D 30/024; H10D 30/43; H10D 30/6211; H10D 30/6219; H10D 30/6729; H10D 30/6735; H10D 30/6757; H10D 62/121; H10D 62/151; H10D 84/013; H10D 84/0149; H10D 84/0158; H10D 84/834

(57) ABSTRACT

A semiconductor device includes a frontside contact over a first source/drain region, a placeholder below the first source/drain region, a backside contact below a second source/drain region, a gate region between the first source/drain region and the second source/drain region, a frontside stress liner wrapping around the gate region, and a backside stress liner wrapping around the placeholder.

### BACKGROUND

### Technical Field

The present disclosure generally relates to semiconductors, and more particularly, to semiconductors with backside contact and stress liner structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a frontside contact over a first source/drain region, a placeholder below the first source/drain region, a backside contact below a second source/drain region, a gate region between the first source/drain region and the second source/drain region, a frontside stress liner wrapping around the gate region, and a backside stress liner wrapping around the placeholder.

In one embodiment, the semiconductor device includes a plurality of nanosheet gates extended horizontally across the gate region and between the first source/drain region and the second source/drain region.

In one embodiment, the semiconductor device includes a self-aligned contact dielectric cap (SAC cap) over the gate region, and a spacer layer covering sidewalls of the gate region and the SAC cap.

In one embodiment, a width of the frontside contact is less than a width of the first source/drain region.

In one embodiment, the placeholder is made of silicon germanium.

In one embodiment, the semiconductor device includes a shallow trench isolation (STI) isolating the frontside stress liner and the backside stress liner, an interlayer dielectric (ILD) over the frontside stress liner, and a bottom ILD (BILD) below the backside stress liner.

In one embodiment, the semiconductor device includes a backside interconnect below the BILD, a back end of line (BEOL) above the ILD, and a carrier wafer over the BEOL.

In one embodiment, the semiconductor device includes a silicide layer vertically extended on opposite ends of the first source/drain region and the second source/drain region. The silicide layer isolates the frontside contact from contact with the spacer layer.

In one embodiment, the frontside stress liner is formed over the second source/drain region and is isolated from contact with the spacer layer by the silicide layer.

According to an embodiment, a method for fabrication of a semiconductor device includes forming first source/drain region, forming a frontside contact over the first source/drain region, forming a placeholder below the first source/drain region. forming a second source/drain region, forming a backside contact below the second source/drain region, forming a gate region between the first source/drain region and the second source/drain region, forming a frontside stress liner to wrap round the gate region, and forming a backside stress liner to wrap around the placeholder.

In one embodiment, the method includes forming a plurality of nanosheet gates extended horizontally across the gate region and between the first source/drain region and the second source/drain region.

In one embodiment, the method includes forming a self-aligned contact dielectric cap (SAC cap) over the gate region, and forming a spacer layer covering sidewalls of the gate region and the SAC cap.

In one embodiment, the method includes isolating the frontside stress liner and the backside stress liner by a shallow trench isolation (STI), forming an interlayer dielectric (ILD) over the frontside stress liner, and forming a bottom ILD (BILD) below the backside stress liner.

In one embodiment, the method includes forming a backside interconnect below the BILD, and forming a back end of line (BEOL) above the ILD.

In one embodiment, the method includes forming a silicide layer vertically extended on opposite ends of the first source/drain region and the second source/drain region, and isolating the frontside contact from contact with the spacer layer by the silicide layer.

In one embodiment, the method includes forming the frontside stress liner over the second source/drain region, and isolating the spacer layer from contact with the frontside stress liner by the silicide layer.

According to an embodiment, a semiconductor device includes a first source/drain region, a second source/drain region, a gate region between the first source/drain region and the second source/drain region, a frontside stress liner wrapping around the gate region, and a backside stress liner below the first source/drain region and the second source/drain region.

In one embodiment, the semiconductor device includes a frontside contact over the first source/drain region, a placeholder below the first source/drain region, and a backside contact below the second source/drain region.

In one embodiment, the semiconductor device includes a plurality of nanosheet gates extended horizontally across the gate region and between the first source/drain region and the second source/drain region, a self-aligned contact dielectric cap (SAC cap) over the gate region, and a spacer layer covering sidewalls of the gate region and the SAC cap.

In one embodiment, the semiconductor device includes a silicide layer vertically extended on opposite ends of the first source/drain region and the second source/drain region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a sideview of a conventional planar transistor.

FIG. 1B illustrates a top view of a conventional planar semiconductor device.

FIG. 2A illustrates a sideview of a conventional nanosheet transistor.

FIG. 2B illustrates a top view of a conventional nanosheet semiconductor device.

FIG. 3A illustrates a side view of a semiconductor device, in accordance with an embodiment.

FIG. 3B illustrates a top view of a semiconductor device, in accordance with an embodiment.

FIG. 4A illustrates a side view of a semiconductor device after the formation of the gate regions, the placeholders, the inner spacer and the source/drain regions, in accordance with an embodiment.

FIG. 4B illustrates a top view of a semiconductor device after the formation of the gate regions, the placeholders, the inner spacer and the source/drain regions, in accordance with an embodiment.

FIG. 5 illustrates a side view of a semiconductor device after the formation of the liner, in accordance with an embodiment.

FIG. 6 illustrates a side view of a semiconductor device after the formation of gate channels and a self-aligned contact dielectric cap, in accordance with an embodiment.

FIG. 7 illustrates a side view of a semiconductor device after the removal of a silicon oxide layer, in accordance with an embodiment.

FIG. 8 illustrates a side view of a semiconductor device after the formation of a silicide layer, in accordance with an embodiment.

FIG. 9 illustrates a side view of a semiconductor device after the formation of a stress liner, in accordance with an embodiment.

FIG. 10A illustrates a side view of a semiconductor device after the formation of a frontside contacts, in accordance with an embodiment.

FIG. 10B illustrates a top view of a semiconductor device after the formation of a frontside contacts, in accordance with an embodiment.

FIG. 11 illustrates a side view of a semiconductor device after the formation of a back end of line and carrier wafer bonding, in accordance with an embodiment.

FIG. 12 illustrates a side view of a semiconductor device after the wafer flipping and removal of a substrate, in accordance with an embodiment.

FIG. 13 illustrates a side view of a semiconductor device after removal of an etch stop layer and remaining substrate, in accordance with an embodiment.

FIG. 14 illustrates a side view of a semiconductor device after the formation of a backside stress liner and a bottom interlayer dielectric, in accordance with an embodiment.

FIG. 15 illustrates a side view of a semiconductor device after the formation of a backside contact, in accordance with an embodiment.

FIG. 16 illustrates a side view of a semiconductor device after the formation of a backside interconnect, in accordance with an embodiment.

FIG. 17 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

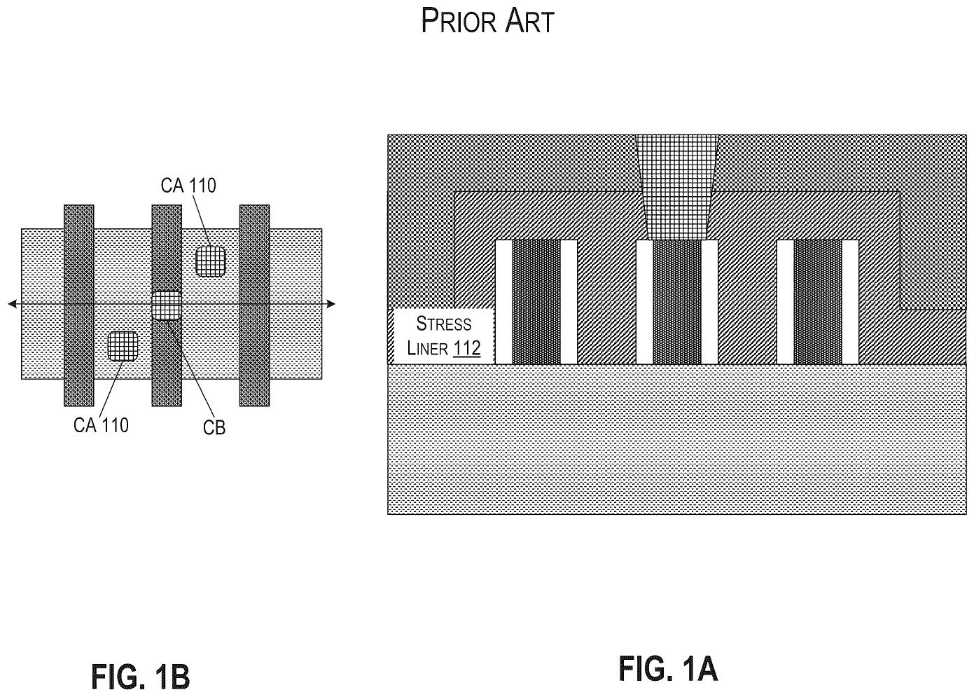

For planar semiconductor devices with a technology node of 22 nanometers and earlier, silicide processes are commonly employed. As shown in FIG. 1A, in such planar devices, frontside contact, CA 110, are made using small vias, which allow for the connection between different layers of the semiconductor. The continuity of stress liner 112, which is used to induce and maintain mechanical stress in the transistor channel to enhance performance, remains intact in these older nodes. The preserved continuity ensures that the desired stress levels in the semiconductor device are maintained, contributing to improved carrier mobility and overall device performance. FIG. 1B shows a top view of the semiconductor device shown in FIG. 1A.

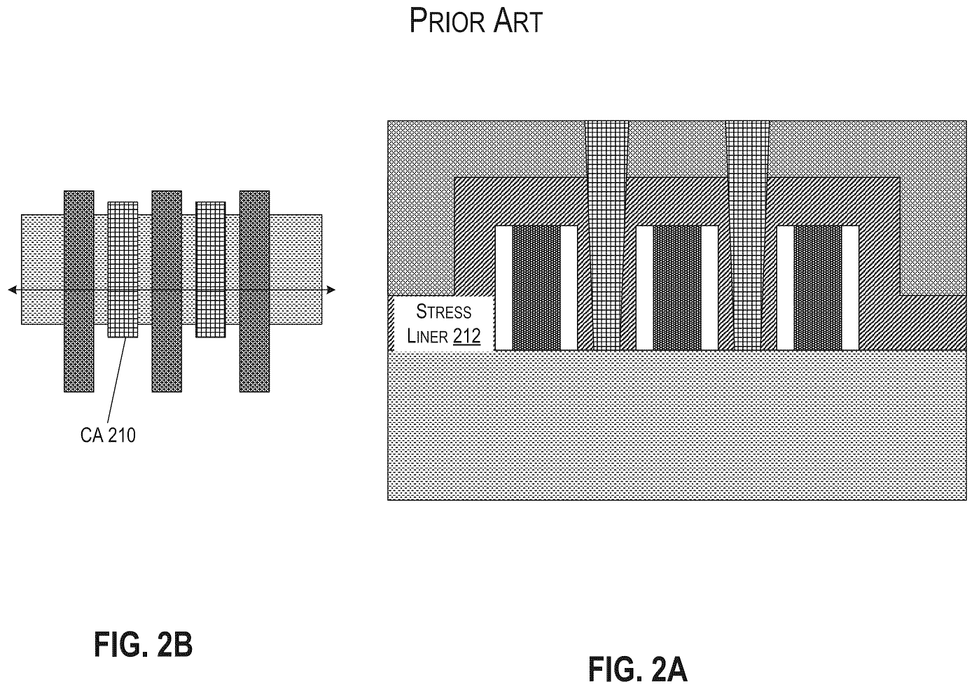

However, as semiconductor technology has advanced to more recent nodes, such as the 14 nanometers node used in field-effect transistors (FETs) or nanosheet transistors, the approach to contact formation has evolved. FIG. 2A shows a conventional FinFET in which trench silicide is employed. The frontside contacts, CA 210, in these devices are no longer confined to small vias; instead, CA 210 is strapped or spanned the entire active regions of the transistor. This design change accommodates the increased complexity and scaling of the device architecture.

Due to these changes, stress liners 212, which were previously effective in inducing beneficial stress in the transistor channel, become less useful. The reason for this is that the contact areas, e.g., CA 210, tend to break the continuity of the stress liners 212. As a result, the mechanical stress that was once preserved and utilized to enhance device performance is disrupted, reducing the effectiveness of stress engineering in these smaller nodes. FIG. 2B shows a top view of the semiconductor device shown in FIG. 2A.

In view of the above considerations, disclosed is a semiconductor device with backside contact and stress liner structure that wraps around the gate regions on the frontside of the semiconductor device, and the placeholders and the backside contact in the backside of the semiconductor device.

Accordingly, the teachings herein provide methods and systems of semiconductor device formation with backside contact and stress liner. The techniques described herein may be implemented in a number of ways. Example implementations are provided below with reference to the following figures.

### Example Semiconductor Device with Backside Contact and Stress Liner Structure

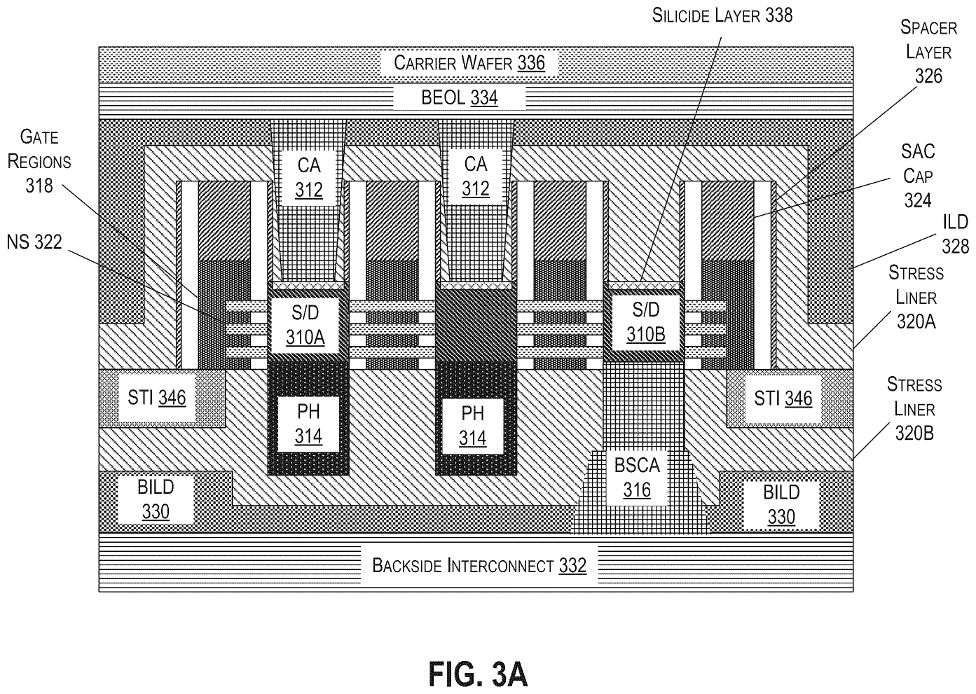

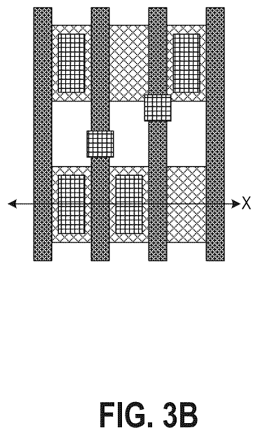

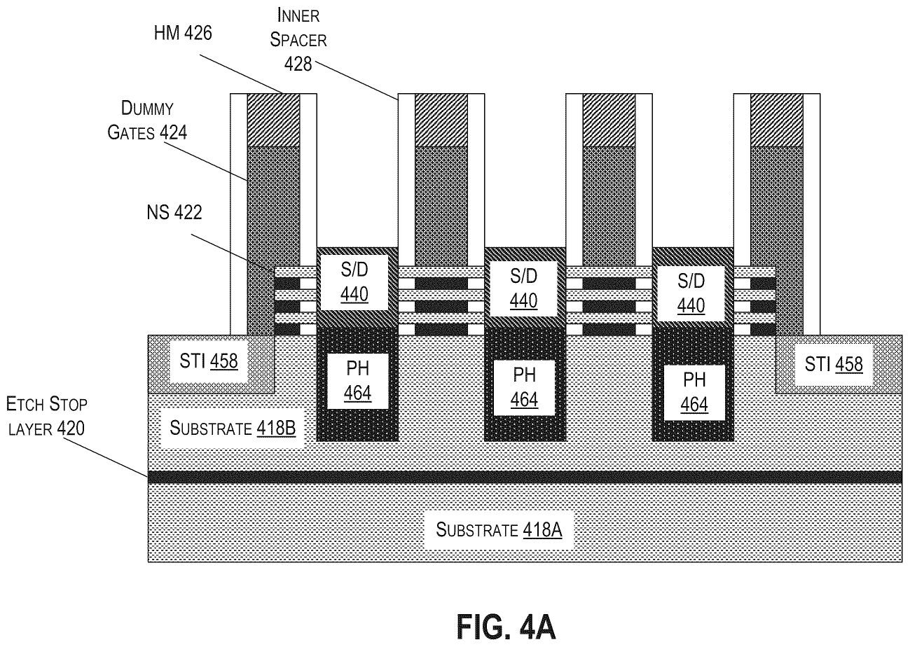

Reference now is made to FIG. 3A, which is a simplified cross-section view of a semiconductor device, consistent with an illustrative embodiment. In various embodiments, the semiconductor device includes a first source/drain region, S/D 310A, a second source/drain region, S/D 310B, a frontside contact, CA 312, a placeholder, PH 314, a backside contact, BSCA 316, a frontside stress liner 320A, a backside stress liner 320B, a plurality of nanosheet gates, NS 322, a self-aligned contact dielectric cap, SAC cap 324, a spacer layer 326, a shallow trench isolation, STI 346, an interlayer dielectric, ILD 328, a bottom ILD, BILD 330, a backside interconnect 332, a back end of line, BEOL 334, a carrier wafer 336, a silicide layer 338, and gate regions 318. FIG. 3B illustrates a top view of a semiconductor device, consistent with an illustrative embodiment.

The CA 312 can be positioned over the S/D 310A. Beneath the S/D 310A, the PH 314 is situated. The BSCA 316 can be located below the S/D 310B. Between the S/D 310A and S/D 310B, gate regions 318 are formed. The gate region 318 can be encircled by a frontside stress liner 320A that wraps around the gate regions 318, providing mechanical stress. Additionally, a backside stress liner 320B can be positioned to wrap around the PH 314.

Generally, the S/D 310A and the S/D 310B are two components that play salient roles in the semiconductor device's operation. In various embodiments, the S/D 310A and the S/D 310B are regions within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied. The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The CA 312 located over the S/D 310A, can establish a connection between the top S/D 310A and the BEOL 334. The CA 312 can ensure efficient electrical routing and connectivity within the semiconductor device. The fabrication of the CA 312 can involve lithography and etching processes to define the contact area. The CA 312 can be made using conductive materials such as copper (Cu) or tungsten (W). In some embodiments, The CA 312 can have a width that is narrower, e.g., smaller, than the width of the S/D 310A. This design can help in optimizing the electrical contact while minimizing interference with surrounding structures.

The PH 314 can be epitaxially grown. The use of the PH 314 can provide more flexibility in the fabrication process, allowing for the creation of complex geometries or the integration of different types of materials. The PH 314 can be made of silicon germanium (SiGe). This material can be selected for its ability to introduce strain into the silicon lattice, which enhances the performance of the semiconductor device by improving carrier mobility.

The BSCA 316 is a region on the backside of the semiconductor device where electrical connections are made. By establishing the electrical contacts, the BSCA 316 can ensure the proper functioning of the semiconductor device and facilitates electrical signal transmission. The BSCA 316 can serve as a thermal interface between the semiconductor device and a heat sink or other cooling mechanisms. By establishing direct contact with the substrate, the BSCA 316 can conduct the heat away from the semiconductor device, and contribute to improved thermal dissipation. In some embodiments, the BSCA 316 can help mitigate parasitic effects, such as substrate coupling or substrate noise, from the semiconductor device. In further embodiments, the BSCA 316 can allow for increased integration density in the semiconductor device.

The gate regions 318 serve as control elements that regulate the flow of current through the semiconductor device. The gate regions 318 can be composed of a conductive material. The gate regions 318 can control the flow of electric current between the source and drain regions. In addition to acting as a switch, modulating the gate voltage can enable the gate regions 318 to control the current flowing through the channel region, resulting in amplified output signals.

In an embodiment, the gate regions 318 can enable the implementation of Boolean active operations, such as AND, OR, and NOT, by controlling the flow of current based on the input voltages. In some embodiments, the gate regions 318, along with other active device components, can facilitate the miniaturization and integration of electronic circuits. The ability to control the channel region's conductivity through the gate voltage allows for compact and highly efficient circuit designs.

In some embodiments, the frontside stress liner 320A can be a tensile stress liner that can induce mechanical stress in the silicon channel of the semiconductor device, which enhances the mobility of charge carriers—either electrons or holes—within the semiconductor device, thereby increasing its speed and efficiency. In such embodiments, the frontside stress liner 320A can apply a stretching force to the silicon channel. This type of stress is particularly effective for transistors where electrons are the primary charge carriers. When the tensile stress stretches the silicon lattice, it can reduce electron scattering, allowing electrons to move more freely through the channel. This improved electron mobility leads to better current flow and overall enhanced performance of the transistor.

In some embodiments, the frontside stress liner 320A can be a compressive stress liner exerting a compressing force on the silicon channel, which enhances the mobility for transistors where holes (the absence of electrons) are the charge carriers. By compressing the silicon lattice, the compressive stress decreases the scattering of holes, thereby improving their mobility. As a result, the transistor operates more efficiently. The frontside stress liner 320A can be made from materials such as silicon nitride and can be deposited over the gate region and S/D 310A and the S/D 310B. In some embodiments, the frontside stress liner 320A can wrap around the gate region 318.

In some embodiments, the backside stress liner 320B can be a tensile stress liner that can induce mechanical stress in the silicon channel of the semiconductor device, which enhances the mobility of charge carriers—either electrons or holes—within the semiconductor device, thereby increasing its speed and efficiency. In such embodiments, the Backside stress liner 320B can apply a stretching force to the silicon channel. This type of stress is particularly effective for transistors where electrons are the primary charge carriers. When the tensile stress stretches the silicon lattice, it can reduce electron scattering, allowing electrons to move more freely through the channel. This improved electron mobility leads to better current flow and overall enhanced performance of the transistor.

In some embodiments, the backside stress liner 320B can be a compressive stress liner exerting a compressing force on the silicon channel, which enhances the mobility for transistors where holes (the absence of electrons) are the charge carriers. By compressing the silicon lattice, the compressive stress decreases the scattering of holes, thereby improving their mobility. As a result, the transistor operates more efficiently. The backside stress liner 320B can be made from materials such as silicon nitride and can be deposited below the PH 314. In some embodiments, the backside stress liner 320B can wrap around the PH 314.

NS 322 can be alternating, vertically oriented sheets, which can drive current in a small footprint area. In some embodiments, NS 322 includes silicon nanowires. In more details, NS 322 includes three-dimensional structures in the gate, which are extended from a source region towards a drain region. The NS 322 can extend horizontally across the gate regions 318. The NS 322 can provide connections between the S/D 310A and the S/D 310B, enhancing the electrical characteristics of the semiconductor device.

The SAC cap 324, which can be positioned over the gate regions 318, can serve to protect and isolate the gate regions 318.

The spacer layer 326 can be thin insulating layers or materials placed on the sidewalls of the gate regions 318. The spacer layer 326 can help control the effective channel length of the semiconductor device. In an embodiment, the spacer layer 326 can allow for control over the channel's conductive properties, including resistance and carrier mobility, which can contribute to improved performance of the semiconductor device. In some embodiments, the spacer layer 326 can help prevent current leakage or short circuits between the gate regions 318 and other parts of the semiconductor device. Such isolation can help maintain the integrity of the semiconductor device's electrical operation and prevent unintended current flow that could negatively impact the performance of the semiconductor device and reliability. In some embodiments, the spacer layer 326 can cover the sidewalls of both the gate regions 318 and the SAC cap 324, ensuring proper alignment and insulation.

STI 346 can electrically isolate different components by filling the trenches with an insulating material, such as silicon dioxide. The STI 346 can prevent electrical interference and crosstalk between adjacent devices, ensuring that each component operates independently without affecting its neighbors. In some embodiments, the STI 346 can be designed to separate the frontside stress liner 320A from the backside stress liner 320B. Such an STI structure can provide electrical isolation between the two stress liners.

The ILD 328 can be a layer of insulating material to electrically isolate and provide mechanical support between different layers of conducting and active components. The ILD 328 can enable efficient signal transmission, reduce crosstalk, and ensure the proper functioning of the semiconductor device. In an embodiment, the ILD 328 can electrically isolate adjacent conducting layers or active components in the semiconductor device. By providing insulation between different layers, the ILD 328 can prevent electrical shorts, reduce (e.g., minimize) leakage current, and ensure that signals are directed only along the desired pathways. In some embodiments, the ILD 328 can help reduce parasitic capacitance between adjacent metal interconnects or active devices and provide mechanical support to the passive device's structure. The ILD 328 can be positioned over the frontside stress liner 320A, serving as an insulating layer.

In several embodiments, the BILD 330 can provide structural support to the semiconductor device by maintaining the mechanical integrity and stability of the semiconductor device. The BILD 330 can further help prevent the warping, bending, or cracking of the substrate, particularly during the manufacturing process or subsequent handling. The BILD 330 can ensure that the semiconductor device remains mechanically robust and maintains its dimensional stability.

In an embodiment, the BILD 330 can also serve as a planarization layer in the semiconductor device fabrication process. As various layers are deposited and patterned on the front side of the semiconductor device, irregularities or topographic variations may arise. The BILD 330 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 330 can contribute to improved overall passive device performance. In several embodiments, BILD 330 can facilitate wafer-level testing of the semiconconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing.

The backside interconnect 332 can provide backside electrical connection between the semiconductor device and other devices. The backside interconnect 332, which can be located below the BILD 330, allows for electrical connections to be made on the backside of the device.

The BEOL 334 can include metal interconnects and other structures on the upper layers of a semiconductor device to form a network of connections that link various components of the semiconductor device. The BEOL 334 can be positioned above the ILD 328 on the frontside of the semiconductor device. In some embodiments, the BEOL 334 can include multiple layers of metal and dielectric materials used for routing electrical signals.

The carrier wafer 336 can be positioned over the BEOL 334 to provide mechanical support during the manufacturing process.

The silicide layer 338 can extend vertically along the opposite ends of the S/D 310A and the S/D 310B. The silicide layer 338 can isolate the CA 312 from contacting the spacer layer 326. Such an isolation can facilitate preventing electrical short circuits and maintaining the integrity of the semiconductor device's operation. The frontside stress liner 320A can be kept from directly contacting the spacer layer 326 by the presence of the silicide layer 338. This configuration maintains the effectiveness of the frontside stress liner 320A while preventing unwanted electrical interactions with the spacer layer 326.

### Example Fabrication of Semiconductor Device with Backside Contact and Stress Liner

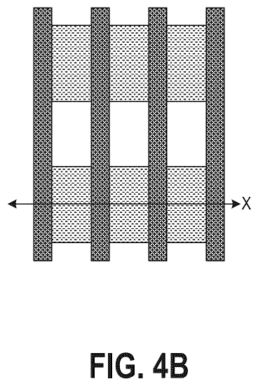

With the foregoing description of an example semiconductor device, it may be helpful to discuss an example process of manufacturing the same. To that end, FIGS. 4-16 illustrate various acts in the manufacture of a semiconductor device, consistent with illustrative embodiments. Figures denoted by A show cross-section views of the semiconductor device after the acts of fabrication of the semiconductor device and figures denoted by B illustrate top views of the semiconductor device after the acts of fabrication of the semiconductor device.

Reference now is made to FIG. 4A, which is a simplified cross-section view of a semiconductor device, after the formation of the gate regions, the placeholder, the inner spacer and the source/drain regions.

The semiconductor device can include a first substrate 418A, a second substrate 418B, an etch stop layer 420, nanosheet gates, NS 422, dummy gates 424, hard masks, HM 426, inner spacer 428, source/drain regions, S/D 440, a STI 458, and placeholders, PH 464.

In the illustrative example depicted in FIG. 4A, the semiconductor device is depicted as being on silicon as the first substrate 418A and the second substrate 418B, while it will be understood that other types as the first substrate 418A and the second substrate 418B may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 418A and the second substrate 418B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 420 is formed over the first substrate 418A. The etch stop layer 420 can be a thin layer of material incorporated into the structure of the semiconductor device to provide a selective barrier against etching processes, preventing further removal of underlying materials during fabrication. The etch stop layer 420 can enable precise control over the etching depth and help define the desired device dimensions. The etch stop layer 420 can further provide a stopping point for the etching process, ensuring that specific layers or regions are not etched beyond a certain point, leading to accurate patterning and control of critical features. The etch stop layer 420 can create a distinct separation between different layers or components within the device structure, and prevent the undesired etching of underlying layers or materials, enabling the creation of complex, multi-layered structures with well-defined interfaces and boundaries. In some embodiments, the etch stop layer 420 acts as a protective barrier for sensitive or delicate materials to shield such materials from aggressive etchants, preventing damage or degradation during subsequent fabrication steps.

In some embodiments, prior to forming the etch stop layer 420, the first substrate 418A is prepared by cleaning and removing any impurities or oxide layers. The etch stop layer 420 is deposited onto the first substrate 418A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 420 can then be selectively etched, stopping at a predetermined depth, while protecting the underlying layers. After the etching process, the remaining photoresist can be removed through stripping techniques. While in some embodiments, SiGe is used to form the etch stop layer 420, in some embodiments, silicon nitride (SiN), silicon oxide (SiO2), or silicon oxynitride (SiON) can be used as the etch stop layer 420.

In some embodiments, the NS 422 can be formed by alternating layers of Si layers and SiGe layers, in which sidewalls of the SiGe layers are indented and covered by the inner spacer 428. The SiGe layers can subsequently be removed and replaced with gate region materials. The NS 422 and the gate regions 430 can be extended over the second substrate 418B and not over the STI 458.

The inner spacer 428 can be thin insulating layers or materials placed on the sidewalls of the gate regions 430. The inner spacer 428 can help control the effective channel length of the semiconductor device. In an embodiment, the inner spacer 428 can allow for control over the channel's conductive properties, including resistance and carrier mobility, which can contribute to improved performance of the semiconductor device. In some embodiments, the inner spacer 428 can be made of a low-k material.

In further embodiments, the HM 426 can be utilized to modulate the overlapping capacitance between the dummy gates 424 and the other parts of the semiconductor device. Overlapping capacitance can affect the semiconductor device's electrical characteristics, such as threshold voltage and switching behavior. Thus, by adjusting the thickness and material properties of the HM 426, the overlapping capacitance can be optimized, which can allow for better control and modulation of the semiconductor device's behavior.

In several embodiments, the HM 426 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability. In some embodiments, the HM 426 can be formed over the sidewalls of the dummy gates 424. The HM 426 can be formed by deposition techniques. Alternatively, the HM 426 can be formed by etching or selectively epitaxially growing the HM 426 over the sidewalls of the dummy gates 424. In various embodiments, the HM 426 can include SiGe.

In an embodiment, the source/drain regions 440 are formed by epitaxial growth. The source/drain regions 440 can be grown with isotropic overburden. FIG. 4B illustrates a top view of the semiconductor device after the formation of the gate regions, the placeholders, the inner spacer and the source/drain regions.

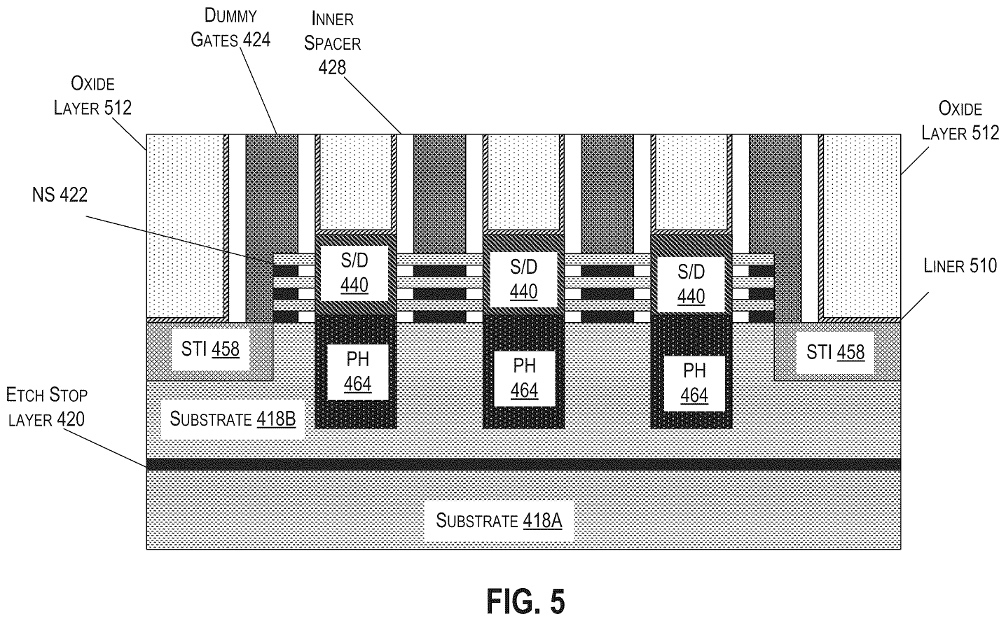

FIG. 5 illustrates a semiconductor device after the formation of the liner, in accordance with some embodiments. In some embodiments, the HM 426 is removed and liner 510 is formed over the top surface of the source/drain regions 440, the exposed surface of the STI 458, and sidewalls of the inner spacer 428. The liner 510 can be made of a silicon nitride, (SiN). An oxide layer 512, e.g., silicon oxide layer, can form over the liner 510.

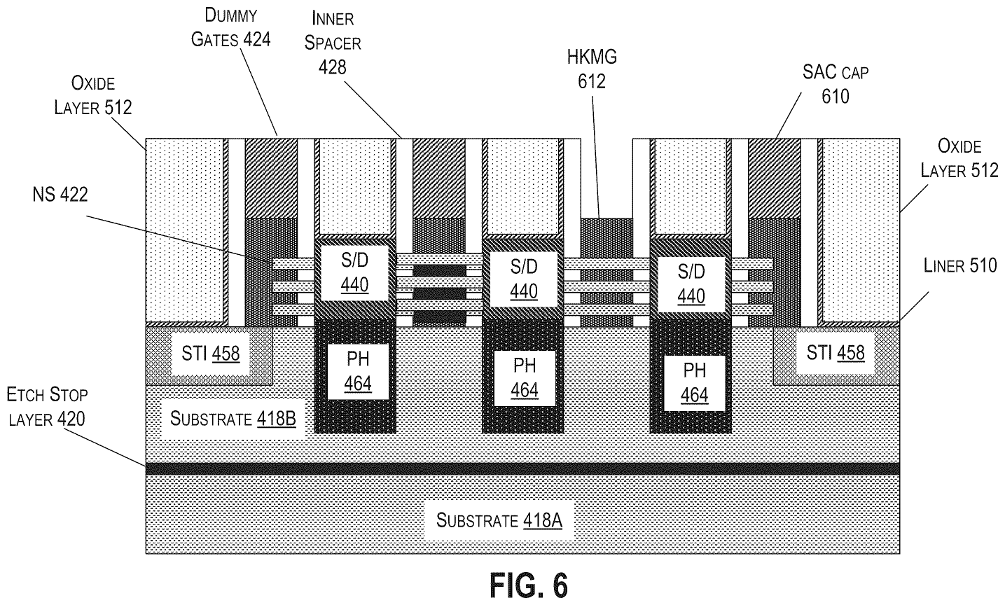

FIG. 6 illustrates a semiconductor device after the formation of the gate channels, in accordance with some embodiments. In some embodiments, the dummy gates and the SiGe layers of the NS are removed and a replacement metal gate (RMG) is performed top form the gate channels, HKMG 612. The RMG process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. A top portion of the gate regions 430 is removed and a SAC cap 610 is formed over the gate regions 430.

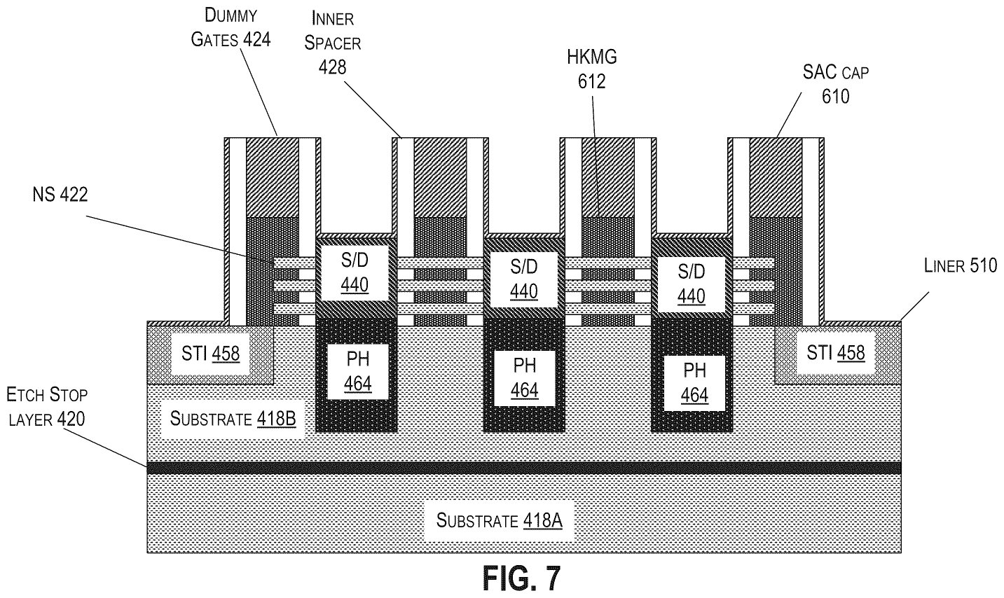

FIG. 7 illustrates a semiconductor device after the removal of the oxide layer, in accordance with some embodiments. In some embodiments, the oxide layer is removed and the liner 510 is exposed.

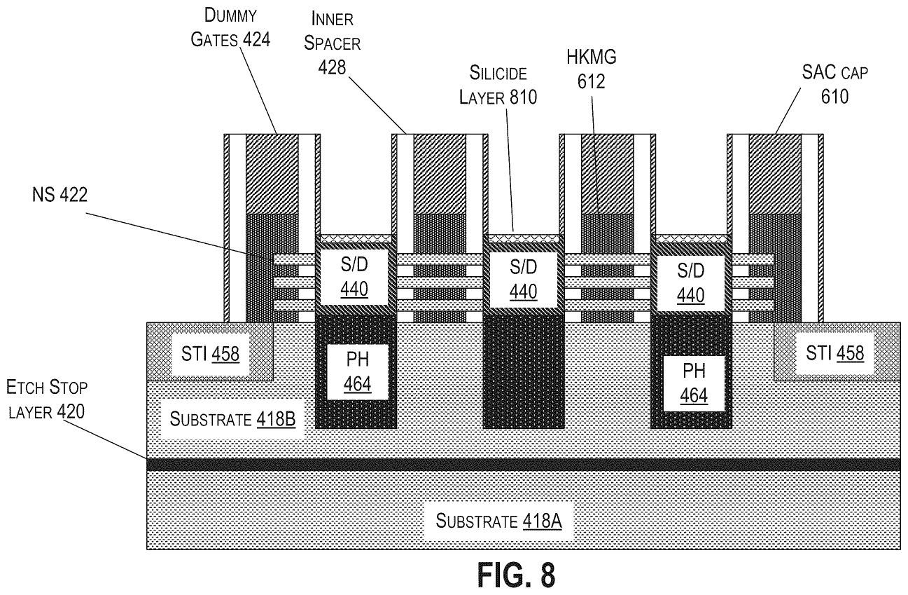

FIG. 8 illustrates a semiconductor device after the formation of the silicide layer, in accordance with some embodiments. In some embodiments, portions of the liner 510 over the source/drain regions 440 are removed and replaced by a silicide layer 810.

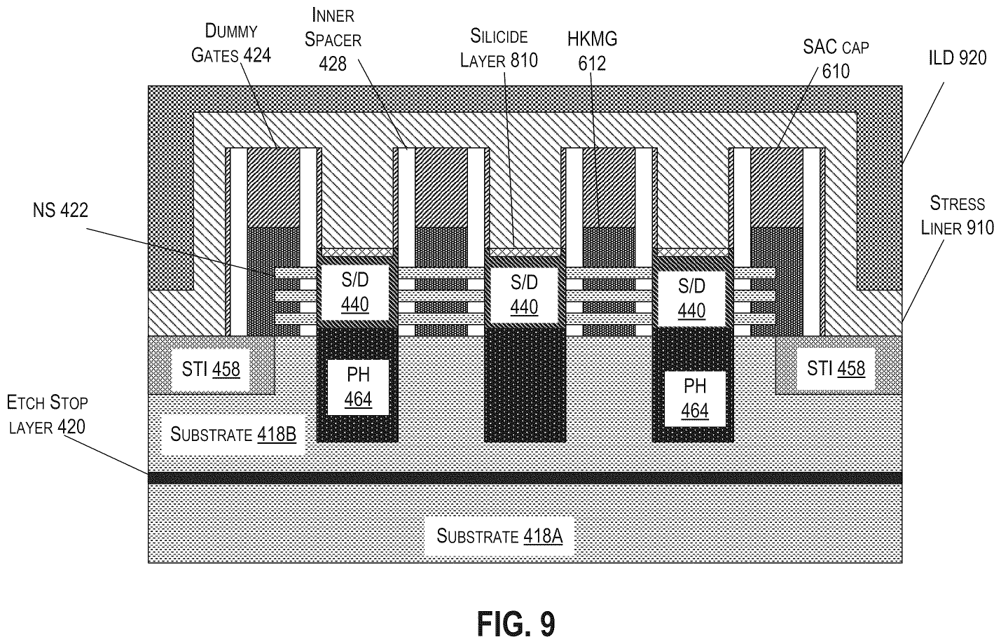

FIG. 9 illustrates a semiconductor device after the formation of the frontside stress liner, in accordance with some embodiments. In some embodiments, a frontside stress liner 910 is formed over the semiconductor device, followed by the formation of an ILD 920. In some embodiments, the ILD 920 is isolated from contact with other components of the semiconductor device below the ILD 920 via the frontside stress liner 910.

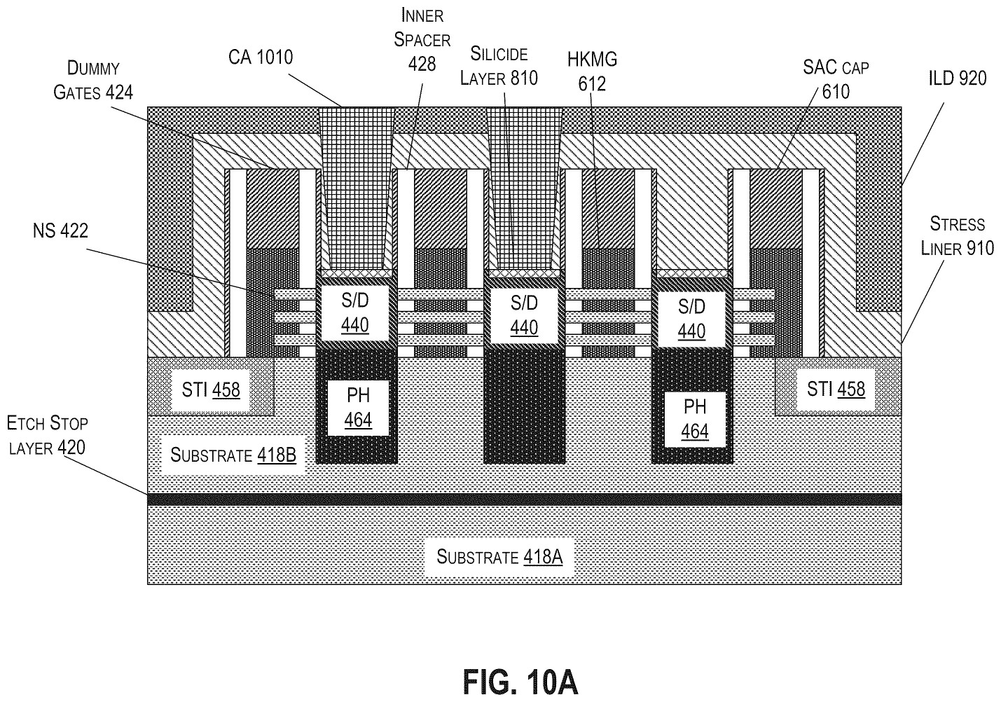

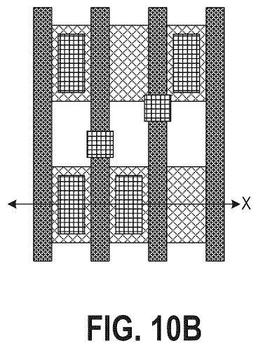

FIG. 10A illustrates a semiconductor device after the middle of line processes, in accordance with some embodiments. In some embodiments, middle of line (MOL) processes is performed to form the frontside contacts, CA 1010, over some of the source/drain regions 440. It should be noted that, at least one of the source/drain regions 440 remains covered by the frontside stress liner 910, e.g., no frontside contact over at least one of the source/drain regions. FIG. 10B illustrates a top view of a semiconductor device after the middle of line processes, in accordance with some embodiments. As noted above, the frontside contact is not required to be formed for every source/drain region. Unlike traditional configurations, where the frontside contact must fully cover or strap the active region, this design allows for more flexibility in contact placement. This flexibility is due to the fact that the use of silicide layer 810 can enhance stress retention when paired with either tensile or compressive stress liners. The silicide layer 810 can maintain the mechanical stress induced by the frontside stress liner 910, whether the stress is tensile (stretching) or compressive (compressing). As a result, the necessity for the frontside contact to fully strap the active region is reduced, because the silicide layer 810 ensures that the desired mechanical stress is preserved throughout the source/drain regions 440. FIG. 10B illustrates a semiconductor device after the middle of line processes, in accordance with some embodiments.

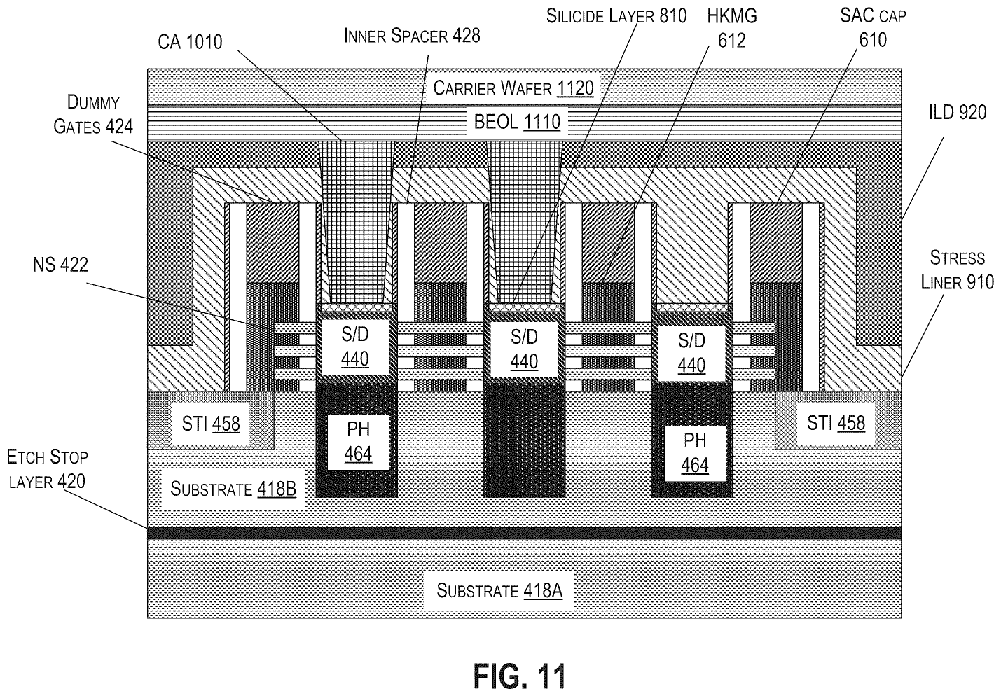

FIG. 11 illustrates a semiconductor device after the formation of the back end of line and the carrier wafer bonding, in accordance with some embodiments. In some embodiments, the BEOL 1110 is formed over the semiconductor device to provide the electrical connections with other devices. In some embodiments, carrier wafer 1120 bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

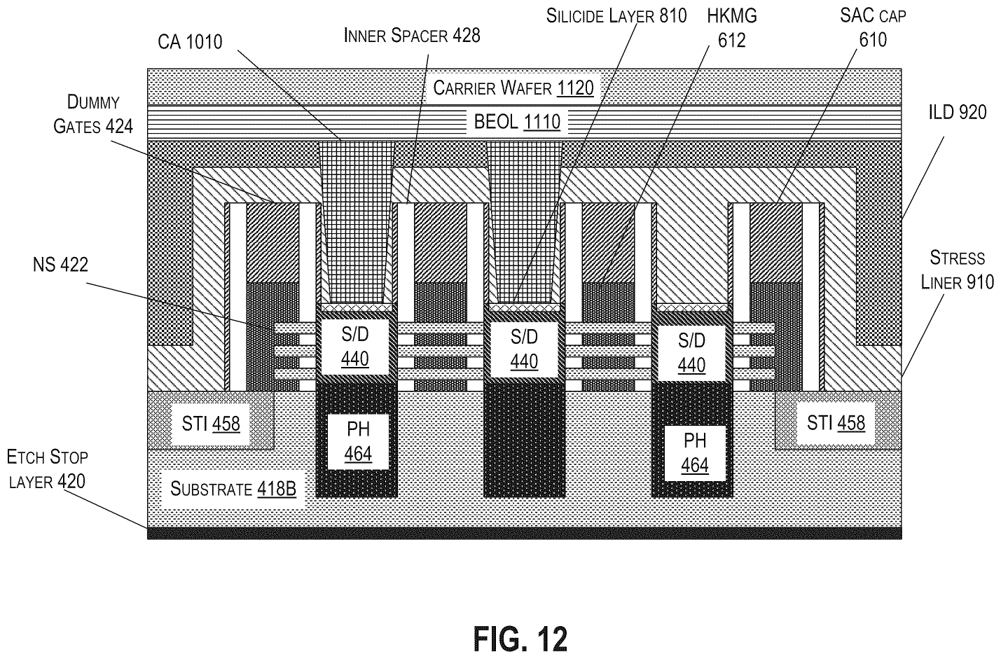

FIG. 12 illustrates a semiconductor device after the removal of the first substrate, in accordance with some embodiments. In some embodiments, the semiconductor device is flipped and the first substrate is removed. The first substrate removal stops at the etch stop layer 420.

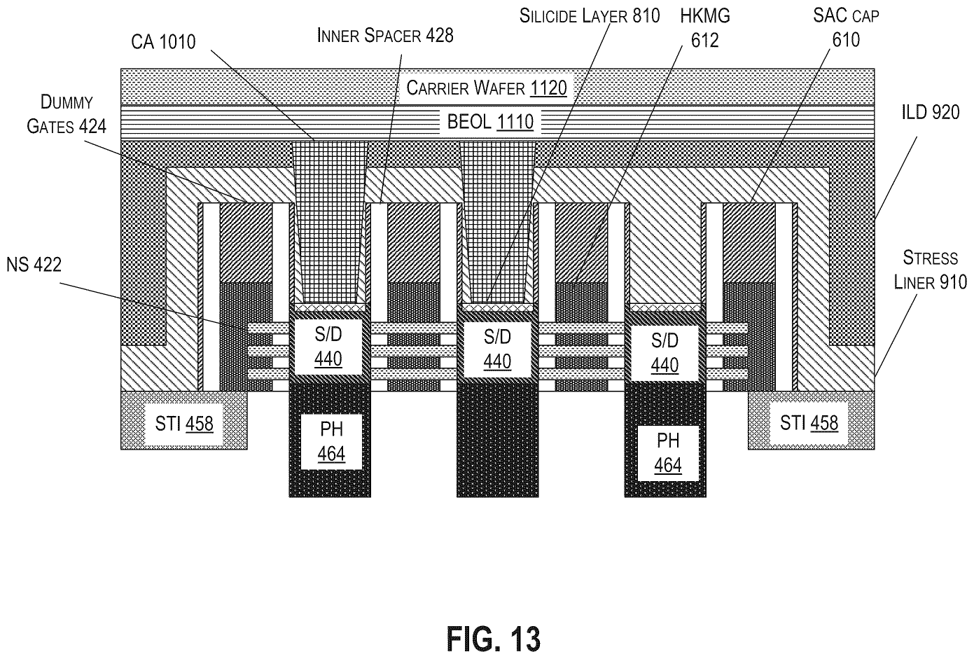

FIG. 13 illustrates a semiconductor device after the after the removal of the etch stop layer, in accordance with some embodiments. In some embodiments, the etch stop layer and the second substrate are removed.

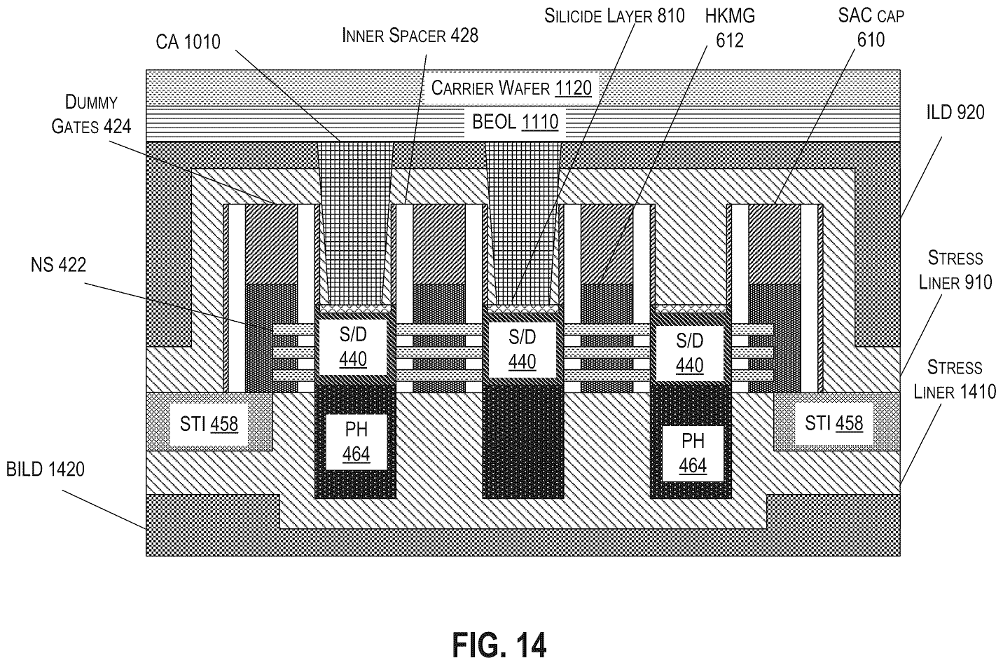

FIG. 14 illustrates a semiconductor device after the after the formation of the backside stress liner, in accordance with some embodiments. In some embodiments, a backside stress liner 1410 is formed over the backside of the semiconductor device, followed by the formation of a BILD 1420. In some embodiments, the BILD 1420 is isolated from contact with other components of the semiconductor device above the BILD 1420 via the backside stress liner 1410.

In various embodiments, the BILD 1420 can function as a protective layer, shielding the active regions of the semiconductor device from external contaminants, moisture, and mechanical stress. The BILD 1420 can further help prevent physical damage, such as scratches or particle contamination, which could adversely affect semiconductor device performance. Additionally, the BILD 1420 can function as a barrier against moisture ingress, which can cause corrosion and degradation of the semiconductor device's components. The BILD 1420 can be made of SiO2.

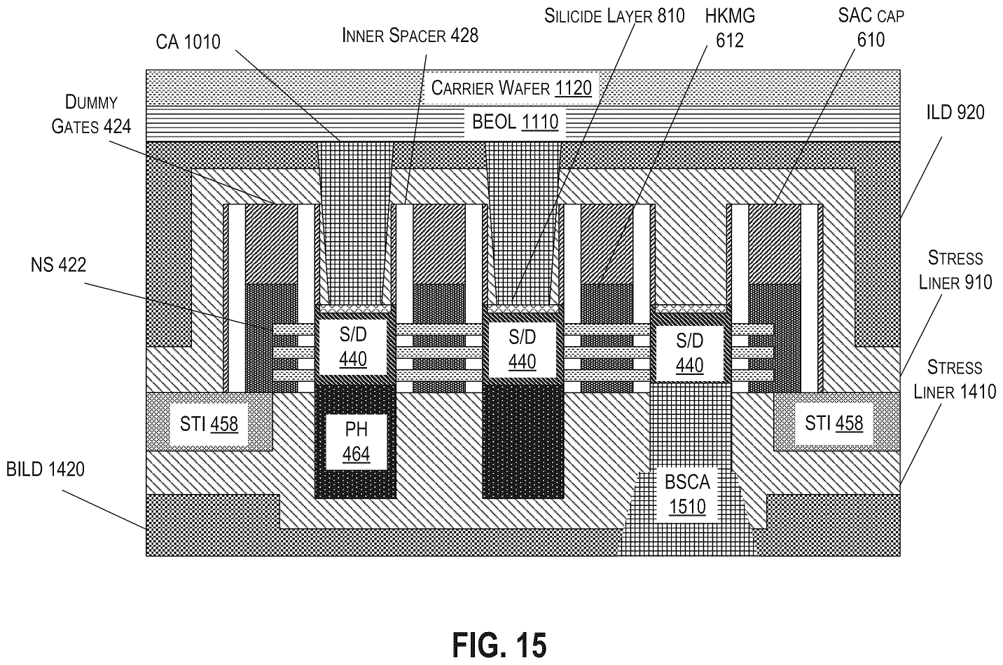

FIG. 15 illustrates a semiconductor device after the backside contact metallization, in accordance with some embodiments. In some embodiments, the backside contacts, BSCA 1510, is formed by removing a placeholder and portions of the BILD 1420 and the backside stress liner 1410 below the source/drain region without a frontside contact, and filling the recessed portions with a suitable metal. The BSCA 1510 can be surrounded in by the BILD 1420.

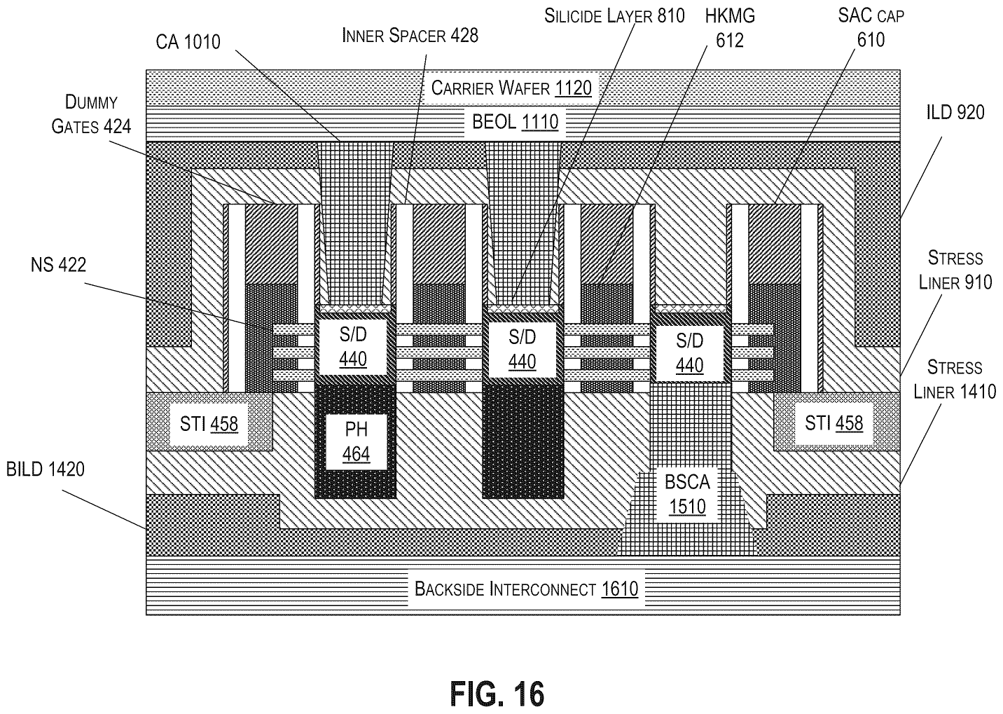

FIG. 16 illustrates a semiconductor device after the formation of the backside interconnect, in accordance with some embodiments. In some embodiments, a backside interconnect 1610 is formed over the backside of the semiconductor device and the BILD 1420.

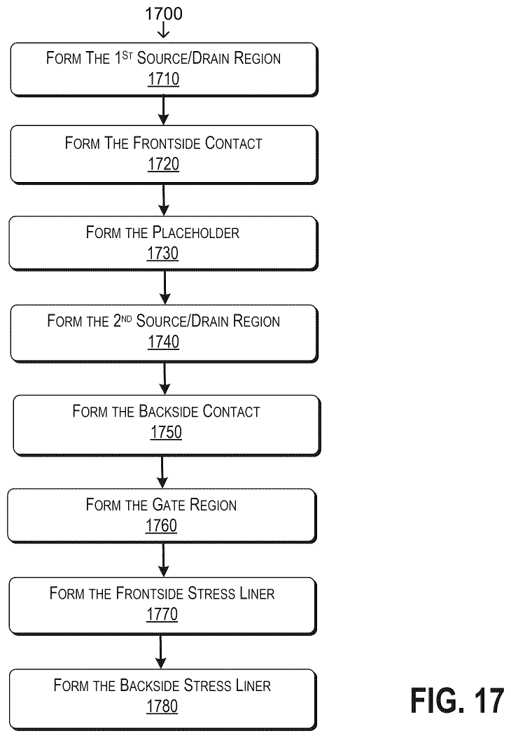

FIG. 17 illustrates a block diagram of a method 1700 for forming the semiconductor device, in accordance with some embodiments. As shown by block 1710, the first source/drain region is formed.

As shown by block 1720, the frontside contact is formed over the first source/drain region.

As shown by block 1730, the placeholder is formed below the first source/drain region.

As shown by block 1740, the second source/drain region is formed.

As shown by block 1750, the backside contact below the second source/drain region is formed.

As shown by block 1760, a gate region between the first source/drain region and the second source/drain region is formed.

As shown by block 1770, a frontside stress liner is formed to wrap around the gate region.

As shown by block 1780, a backside stress liner is formed to wrap around the placeholder.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a frontside contact over a first source/drain region;
a placeholder below the first source/drain region;
a backside contact below a second source/drain region;
a gate region between the first source/drain region and the second source/drain region;
a frontside stress liner wrapping around the gate region; and
a backside stress liner wrapping around the placeholder.

2. The semiconductor device of claim 1, further comprising a plurality of nanosheet gates extended horizontally across the gate region and between the first source/drain region and the second source/drain region.

3. The semiconductor device of claim 1, further comprising:
a self-aligned contact dielectric cap (SAC cap) over the gate region; and
a spacer layer covering sidewalls of the gate region and the SAC cap.

4. The semiconductor device of claim 1, wherein a width of the frontside contact is less than a width of the first source/drain region.

5. The semiconductor device of claim 1, wherein the placeholder is made of silicon germanium.

6. The semiconductor device of claim 1, further comprising:
a shallow trench isolation (STI) isolating the frontside stress liner and the backside stress liner;
an interlayer dielectric (ILD) over the frontside stress liner; and
a bottom ILD (BILD) below the backside stress liner.

7. The semiconductor device of claim 6, further comprising:
a backside interconnect below the BILD;
a back end of line (BEOL) above the ILD; and
a carrier wafer over the BEOL.

8. The semiconductor device of claim 1, further comprising a silicide layer vertically extended on opposite ends of the first source/drain region and the second source/drain region, wherein the silicide layer isolates the frontside contact from contact with a spacer layer.

9. The semiconductor device of claim 8, wherein the frontside stress liner is formed over the second source/drain region and is isolated from contact with the spacer layer by the silicide layer.

10. A method of fabricating a semiconductor device, the method comprising:
forming a first source/drain region;
forming a frontside contact over the first source/drain region;
forming a placeholder below the first source/drain region;
forming a second source/drain region;
forming a backside contact below the second source/drain region;
forming a gate region between the first source/drain region and the second source/drain region;
forming a frontside stress liner to wrap around the gate region; and
forming a backside stress liner to wrap around the placeholder.

11. The method of claim 10, further comprising forming a plurality of nanosheet gates extended horizontally across the gate region and between the first source/drain region and the second source/drain region.

12. The method of claim 10, further comprising:
forming a self-aligned contact dielectric cap (SAC cap) over the gate region; and
forming a spacer layer covering sidewalls of the gate region and the SAC cap.

13. The method of claim 10, further comprising:
isolating the frontside stress liner and the backside stress liner by a shallow trench isolation (STI);
forming an interlayer dielectric (ILD) over the frontside stress liner; and
forming a bottom ILD (BILD) below the backside stress liner.

14. The method of claim 13, further comprising:
forming a backside interconnect below the BILD; and
forming a back end of line (BEOL) above the ILD.

15. The method of claim 10, further comprising:
forming a silicide layer vertically extended on opposite ends of the first source/drain region and the second source/drain region; and
isolating the frontside contact from contact with a spacer layer by the silicide layer.

16. The method of claim 15, further comprising:
forming the frontside stress liner over the second source/drain region; and
isolating the spacer layer from contact with the frontside stress liner by the silicide layer.

17. A semiconductor device, comprising:
a first source/drain region;
a second source/drain region;
a gate region between the first source/drain region and the second source/drain region;
a frontside stress liner wrapping around the gate region; and
a backside stress liner below the first source/drain region and the second source/drain region.

18. The semiconductor device of claim 17, further comprising:
a frontside contact over the first source/drain region;
a placeholder below the first source/drain region; and
a backside contact below the second source/drain region.

19. The semiconductor device of claim 17, further comprising:
a plurality of nanosheet gates extended horizontally across the gate region and between the first source/drain region and the second source/drain region;
a self-aligned contact dielectric cap (SAC cap) over the gate region; and
a spacer layer covering sidewalls of the gate region and the SAC cap.

20. The semiconductor device of claim 17, further comprising a silicide layer vertically extended on opposite ends of the first source/drain region and the second source/drain region.
